(19) United States
(12) Patent Application Publication
(10) Pub. No.: US 2025/0226247 A1
(43) Pub. Date: Jul. 10, 2025

(54) SEMICONDUCTOR PROCESSING APPARATUS

(71) Applicant: Samsung Electronics Co., Ltd., Suwon-si (KR)

(72) Inventors: SOONKU KWON, Suwon-si (KR); WOOJIN NAM, Suwon-si (KR); SUNGGIL KANG, Suwon-si (KR); SUNGYONG PARK, Suwon-si (KR); JEONGMIN BANG, Suwon-si (KR); SEJIN OH, Suwon-si (KR); YEONGKWANG LEE, Suwon-si (KR)

(21) Appl. No.: 18/746,268

(22) Filed: Jun. 18, 2024

(30) Foreign Application Priority Data
Jan. 9, 2024 (KR) 10-2024-0003418

(51) Int. Cl. H01L 21/67; G01N 21/31; H01J 37/32

(52) U.S. Cl. CPC H01L 21/67253; G01N 21/31; H01J 37/32422; H01J 37/32917; H01J 2237/2445; H01J 2237/24507

(57) ABSTRACT

A semiconductor processing apparatus includes a chamber housing having one window, a light source configured to emit light within a predetermined wavelength band, an optical path controller including a first mirror configured to reflect the light as a first optical signal that enters an internal space of the chamber housing through the window, and a second mirror configured to reflect the first optical signal after it exits the internal space through the window, a photodetector configured to detect a first intensity of the first optical signal, and a processor configured to adjust the first mirror and the second mirror to obtain a second intensity of a second optical signal, traveling along a second path different from a first path of the first optical signal, in the internal space, from the photodetector, and determine a radical distribution in the internal space based on the first intensity and the second intensity.

### CROSS-REFERENCE TO RELATED APPLICATION(S)

This application claims the benefit under 35 USC 119(a) of Korean Patent Application No. 10-2024-0003418 filed on Jan. 9, 2024 in the Korean Intellectual Property Office, the entire disclosure of which is incorporated herein by reference for all purposes.

### BACKGROUND OF THE INVENTION

The present inventive concept relates to a semiconductor processing apparatus.

In the case of a wet clean process using liquid, there may be limitations in microprocessing at the level of several nanometers (nm) due to the surface tension of the liquid. To reduce such limitations, a dry clean process using highly reactive gases or radicals has recently emerged. To improve the yield of the dry clean process and maintain stability in a situation in which the size of a wafer increases to increase the number of chips that may be produced in one process, it may be beneficial to maintain uniform radical density in the space above the wafer. Therefore, a method for monitoring radical density may be beneficial while the semiconductor process is in progress.

### SUMMARY OF THE INVENTION

Example embodiments provide a semiconductor processing apparatus that may determine distribution of radicals in an internal space, using an optical signal entering the internal space of a chamber housing through one window of the chamber housing and then reflected at least once in the internal space.

According to example embodiments, a semiconductor processing apparatus includes a chamber housing having only one window, a substrate support in an internal space of the chamber housing, a light source configured to emit light within a predetermined wavelength band, an optical path controller including a first mirror configured to reflect the light as a first optical signal that enters the internal space of the chamber housing through the window, and a second mirror configured to reflect the first optical signal after it exits the internal space through the window, a photodetector configured to detect a first intensity of the first optical signal, and a processor configured to adjust the first mirror and the second mirror to obtain a second intensity of a second optical signal, traveling along a second path different from a first path of the first optical signal, in the internal space, from the photodetector, and determine a radical distribution in the internal space based on the first intensity and the second intensity.

According to example embodiments, a semiconductor processing apparatus includes a chamber housing having a single window, a substrate support in an internal space of the chamber housing, and a plasma source in the internal space of the chamber housing, an ion blocker dividing the internal space of the chamber housing into a first space in which the plasma source is configured to generate plasma, and a second space in which the substrate support is located, and including a plurality of regions each having a plurality of through-holes, a temperature control unit configured to individually control temperature of each of the plurality of regions, an optical path controller attached to the window, and configured to generate an optical signal that enters the second space through the window, reflects in the internal space, and then returns to the window, and a processor. The processor is configured to determine a radical distribution of the second space by detecting an intensity of the optical signal when radicals of the plasma move into the second space through the plurality of through-holes.

According to example embodiments, a semiconductor processing apparatus includes a chamber housing having a single window, a plasma source in an internal space of the chamber housing, a substrate support in the internal space of the chamber housing, an ion blocker in the internal space of the chamber housing and including a plurality of through-holes each providing a path for movement of radicals of plasma that the plasma source is configured to generate in response to power applied to the plasma source, and an optical path controller attached to the window. The ion blocker divides the internal space of the chamber housing into a first space with the plasma source therein and with the plasma generated therein, and a second space with the substrate support therein. The window may face the second space. The optical path controller includes a first mirror that is configured to reflect light as an optical signal that enters the second space through the window, and a second mirror that is configured to reflect the optical signal after it is reflected in the second space and then returned through the window.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram simply illustrating a system including a semiconductor processing apparatus according to example embodiments;

FIGS. 2 and 3 are schematic diagrams of a semiconductor processing apparatus according to example embodiments;

FIG. 4 is a diagram schematically illustrating a semiconductor processing apparatus according to example embodiments;

FIG. 5 is a diagram schematically illustrating an optical path controller included in a semiconductor processing apparatus according to example embodiments;

FIGS. 6 and 7 are diagrams illustrating the operation of a semiconductor processing apparatus according to example embodiments;

FIGS. 8 and 9 are diagrams illustrating the operation of a semiconductor processing apparatus according to example embodiments;

FIGS. 10 and 11 are diagrams illustrating the operation of a semiconductor processing apparatus according to example embodiments;

FIGS. 12 and 13 are diagrams illustrating the operation of a semiconductor processing apparatus according to example embodiments;

FIGS. 14 and 15 are diagrams illustrating a method of measuring radical distribution in a semiconductor processing apparatus according to example embodiments;

FIG. 16 is a diagram illustrating the operation of a semiconductor processing apparatus according to example embodiments; and

FIG. 17 is a diagram illustrating the operation of a semiconductor processing apparatus according to example embodiments.

### DETAILED DESCRIPTION

Hereinafter, example embodiments will be described with reference to the accompanying drawings.

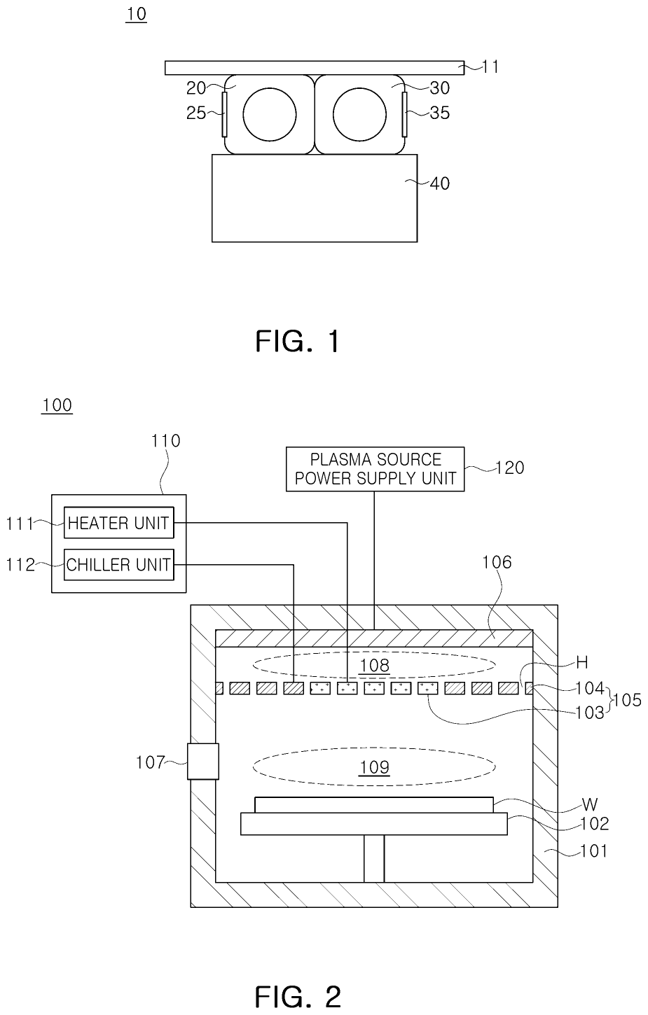

FIG. 1 is a diagram simply illustrating a system including a semiconductor processing apparatus according to example embodiments.

Referring to FIG. 1, a system 10 according to example embodiments may include a plurality of semiconductor processing apparatuses 20 and 30 and a wafer transfer device 40 installed within a building 11. Each of the plurality of semiconductor processing apparatuses 20 and 30 may be equipment that receives a wafer from the wafer transfer device 40 and performs semiconductor processes such as deposition, cleaning, etching, and the like.

The wafer transfer device 40 may receive a container such as a Front Open Unified Pod (FOUP) containing wafers from inside the building 11 where the system 10 is installed. The wafer transfer device 40 may take out wafers stored in the FOUP and transfer the wafers to the plurality of semiconductor processing apparatuses 20 and 30, or receive the wafers in which the semiconductor process has been completed from the plurality of semiconductor processing apparatuses 20 and 30 and may store the wafers in the FOUP again.

Each of the plurality of semiconductor processing apparatuses 20 and 30 may perform a semiconductor process on a wafer. For example, a semiconductor process performed by the plurality of semiconductor processing apparatuses 20 and 30 may include a deposition process, a cleaning process, an etching process, an exposure process, an annealing process, a polishing process, an ion implantation process, and the like. Depending on the semiconductor process to be performed, plasma may be formed inside each of the plurality of semiconductor processing apparatuses 20 and 30.

For example, to increase the yield of a semiconductor process performed with formed plasma, radicals and the like generated by plasma may need to be uniformly distributed in the internal space of each of the plurality of semiconductor processing apparatuses 20 and 30. For example, the more uniform the distribution of radicals in the internal space above the substrate support on which the wafer is disposed, the difference in yield of the semiconductor process for respective semiconductor dies disposed at different positions on the wafer may be reduced.

In example embodiments, the distribution of radicals in the internal space of the chamber housing may be monitored through one window 25, 35 installed in the chamber housing in each of the plurality of semiconductor processing apparatuses 20 and 30. Therefore, there is no need to install a plurality of windows 25 and 35 on different surfaces of the chamber housing, and as illustrated in FIG. 1, a plurality of semiconductor processing apparatuses 20 and 30 may be installed in the building 11 in the form of a twin chamber in which two semiconductor processing apparatuses 20 and 30 are in close contact.

To monitor the distribution of radicals in the internal space of the chamber housing through one window 25, 35, in example embodiments, an optical path controller may be installed in the windows 25 and 35. The optical path controller is connected to the light source and photodetector, and may include mirrors that may change the path of an optical signal that is emitted from the light source and then enters the internal space through the windows 25 and 35, and the path of an optical signal that is reflected one or more times in the internal space and then enters the photodetector through the windows 25 and 35.

The optical signal that travels and is reflected in the internal space of the chamber housing may be absorbed by radicals distributed in the internal space in at least some wavelength bands. Therefore, by changing the path of the optical signal using mirrors and measuring the intensity of the optical signal with photodetectors, the distribution of radicals in the internal space of the chamber housing may be monitored in real time. Additionally, the yield of the semiconductor process may be improved by controlling each of the semiconductor processing apparatuses 20 and 30 using the monitoring results.

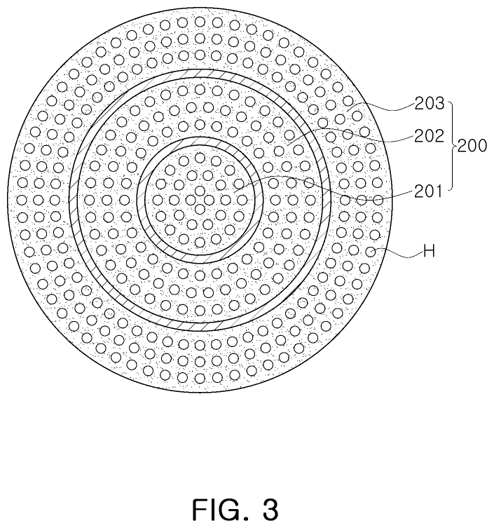

FIGS. 2 and 3 are schematic diagrams of a semiconductor processing apparatus according to example embodiments.

First, referring to FIG. 2, a semiconductor processing apparatus 100 according to example embodiments may include a chamber housing 101, a substrate support 102, an ion blocker 105, a plasma source 106, a temperature control unit 110, a plasma source power supply unit 120, and the like. The chamber housing 101 may include a first space 108 and a second space 109.

The first space 108 and the second space 109 may be separated by the ion blocker 105. The plasma source 106 may be disposed in the first space 108, and plasma may be generated by power applied to the plasma source 106. The substrate support 102 may be disposed in the second space 109, and a semiconductor process for a wafer W may be performed in the second space 109.

In example embodiments, the internal space of the chamber housing 101 may have a cylindrical shape, and the chamber housing 101 may be formed of a metal such as aluminum (Al). The chamber housing 101 may be grounded, and an opening for loading/unloading the wafer W may be formed in at least one of the other walls on which the window 107 is not formed. Additionally, an exhaust pipe that discharges by-products generated during the process may be connected to the lower wall of the chamber housing 101 or the like. A pump that maintains the inside of the chamber housing 101 at the process pressure during the process and a valve that opens and closes the passage in the exhaust pipe may be installed in the exhaust pipe.

The chamber housing 101 may be provided with the substrate support 102 therein. A heating member may be installed inside the substrate support 102 as a means to control the temperature of the wafer W. The wafer W may be maintained at a temperature required for the semiconductor process by the heat generated from the heating member.

Additionally, a cooling passage constituting a cooling unit may be formed inside the substrate support 102, and a cooling fluid may be provided in the cooling passage. The cooling fluid may cool the wafer W while flowing along the cooling passage to maintain the wafer W at the temperature required for the process.

The plasma source power supply unit 120 may supply power to the plasma source 106 disposed in the first space 108. In an example embodiment illustrated in FIG. 2, the plasma source 106 is illustrated as attached to the top of the chamber housing 101, but the plasma source 106 may be attached on another location inside the chamber housing 101. The plasma source power supply unit 120 may apply radio frequency power (RF power) or microwave power to the plasma source 106. For example, the plasma source power supply unit 120 may include a matching network, an RF power source for generating power, and the like.

The ion blocker 105 may divide the internal space into the first space 108 and the second space 109 as upper and lower portions. For example, process gas may be provided to the first space 108 by a gas supply unit connected to the chamber housing 101. The electromagnetic field formed between the plasma source 106 and the ion blocker 105 may excite the process gas into a plasma state. The process gas excited in a plasma state may contain radicals, ions, electrons, and the like.

The ion blocker 105 is formed of a conductive material, and in example embodiments, may have a plate shape such as a disk. A constant voltage (for example, ground voltage) may be supplied to the ion blocker 105, but is not necessarily limited to this example. The ion blocker 105 may include a plurality of through-holes H that each provide a connecting passage (e.g., a path) between the first space 108 and the second space 109 in the vertical direction.

Among radicals, ions, and electrons contained in the process gas excited in a plasma state in the first space 108, radicals or uncharged neutral particles may pass through the through-holes H of the ion blocker 105 and move into the second space 109. Meanwhile, charged ions and the like may have difficulty in passing through the through-holes H.

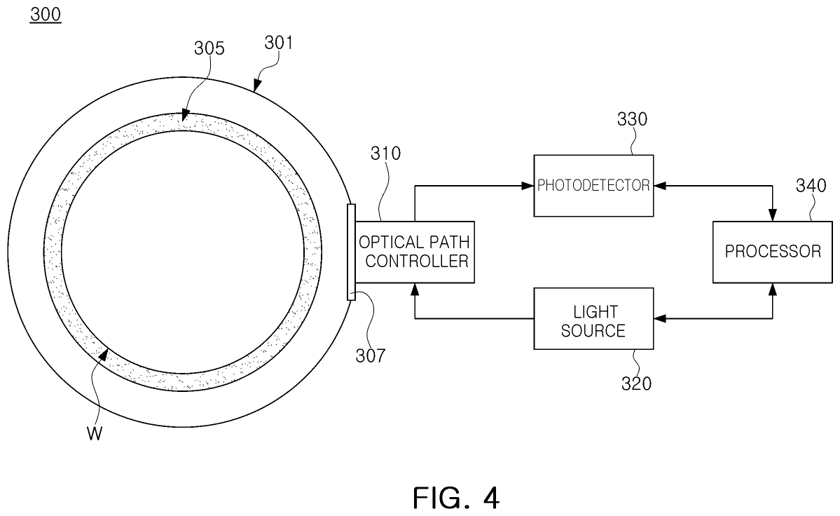

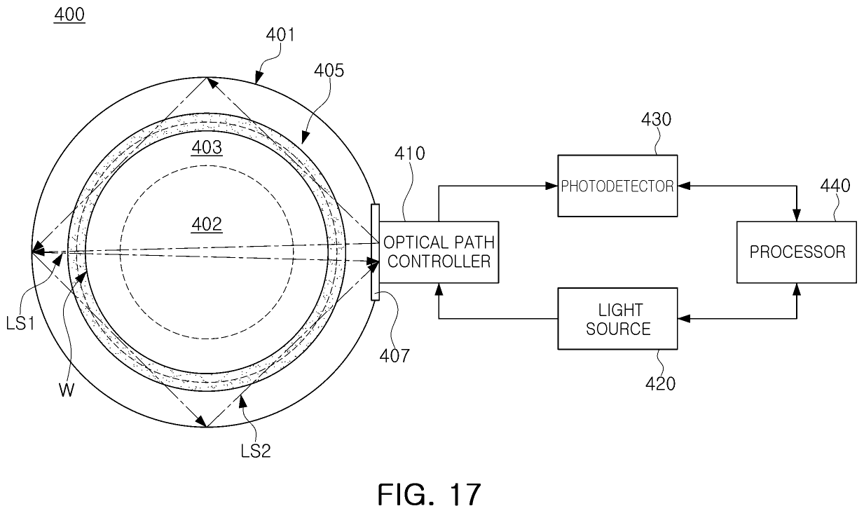

In example embodiments, the ion blocker 105 includes a plurality of regions 103 and 104 and may be connected to the temperature control unit 110. The temperature control unit 110 may include a heater unit 111 and a chiller unit 112. The temperature control unit 110 may individually control the temperature of each of the plurality of regions 103 and 104 included in the ion blocker 105. In some embodiments, a processor (e.g., a processor 340 (FIG. 4) or a processor 440 (FIG. 17)) can control the temperature control unit 110 to change a temperature of at least one of the plurality of regions 103 and 104, based on a radical density of each of a plurality of internal regions in the second space 109.

The plurality of regions 103 and 104 include a first region 103 and a second region 104, and the first region 103 may be located further inwardly than the second region 104. For example, the second region 104 may be formed to surround at least a portion of the first region 103. The first region 103 is the center area of the ion blocker 105 that vertically overlaps the center area of the wafer W, and the second region 104 may be an edge area of the ion blocker 105 that vertically overlaps the edge area of the wafer W. Depending on example embodiments, the first region 103 and the second region 104 may be formed in a concentric circle shape. In an example embodiment illustrated in FIG. 2, the ion blocker 105 is illustrated as including the first region 103 and the second region 104, but the number of regions included in the ion blocker 105 may vary as needed. For example, the ion blocker 105 may include three or more regions where temperature may be individually controlled.

A cooling passage connected to the chiller unit 112 may be disposed in the boundary area defined between the plurality of regions 103 and 104. For example, a cooling passage disposed in the boundary area between the first region 103 and the second region 104 may be connected to the chiller unit 112. Accordingly, thermal separation of the plurality of respective regions 103 and 104 may be strengthened. However, the connection structure of the plurality of regions 103 and 104 with the heater unit 111 and the chiller unit 112 is not necessarily limited to this example. Hereinafter, the configuration of the ion blocker 105 will be described in more detail with reference to FIG. 3.

Referring to FIG. 3, an ion blocker 200 according to example embodiments may include first to third regions 201-203, and boundary areas may be defined between the first to third regions 201-203. The first to third regions 201-203 may be connected to the heater unit 111 (FIG. 2). For example, the heater unit 111 may be configured so that the temperature of each of the first to third regions 201-203 may be individually controlled.

Boundary areas between the first to third regions 201-203 may be connected to the chiller unit 112 (FIG. 2). Similar to the first to third regions 201-203, the chiller unit 112 may be configured to individually control the temperature of each boundary region. By connecting the chiller unit 112 to the boundary areas between the first to third regions 201-203, the first to third regions 201-203 may be reliably thermally separated.

Each of the first to third regions 201-203 may include a plurality of through-holes H. In example embodiments, the diameter of each of the plurality of through-holes H may be smaller than twice the thickness of the plasma sheath, and for example, may be 1 millimeters (mm) or less.

In example embodiments, the yield of a process performed on a wafer may vary depending on the density and/or distribution of radicals flowing into the second space defined between the ion blocker 200 and the substrate support. The density and/or distribution of radicals may be determined by the distribution of plasma generated in the first space (e.g., the first space 108 (FIG. 2)) above the ion blocker 200 and the airflow of the process gas. In example embodiments, by independently controlling the temperature of each of the plurality of regions 201-203 included in the ion blocker 200, the radical density and/or distribution of the second space (e.g., the second space 109 (FIG. 2)) defined between the ion blocker 200 and the substrate support (e.g., the substrate support 102 (FIG. 2)) may be optimally controlled.

As illustrated in FIG. 2, a window 107 may be installed in at least one of the walls constituting the chamber housing 101. For example, the window 107 may be installed in one of the side walls of the chamber housing 101 and may be installed above the substrate support 102 so that the second space 109 may be identified. The window 107 may thus face the second space 109. In example embodiments, the window 107 may be installed within 10 mm from the upper surface of the substrate support 102 in the vertical direction. In a direction (e.g., the vertical direction) perpendicular to the upper surface of the substrate support 102, the window 107 may be located closer to the substrate support 102 than the ion blocker 105.

Through the window 107, the distribution of radicals passing through the through-holes H of the ion blocker 105 and flowing into the second space 109 may be confirmed. For example, the distribution of radicals may be determined by injecting an optical signal through the window 107 and detecting the intensity of the optical signal having passed through the second space 109. For example, the greater the difference in intensity between the optical signal incident through the window 107 and the optical signal passing through the second space 109, it may be determined that the more the optical signal is absorbed by the radicals and the higher the density of radicals is.

To detect the intensity of the optical signal that entered through the window 107 and then passed through the second space 109, a window may need to be installed on another wall opposite to the wall where the window 107 is installed. However, constraints may arise, such as the semiconductor processing apparatus 100 being placed continuously in pairs or adjacent to the corner of a building, or the like. In this case, it may be impossible to respectively install the windows 107 on facing walls.

In example embodiments, the distribution and/or density of radicals may be determined using only one window 107. For example, an optical path controller may be attached to one window 107 and the path of the optical signal within the second space 109 may be controlled using the optical path controller. By using an optical path controller, optical signals traveling along different paths may be incident through the window 107, and the optical signal reflected one or more times from the inner wall of the chamber housing 101 while passing through the second space 109 may enter the optical path controller through the window 107. Therefore, by detecting the intensity of optical signals moving along different paths through one window 107, the radical density and/or distribution in the second space 109 may be determined, and based thereon, the semiconductor processing apparatus 100 may be controlled in real time to improve the yield of the semiconductor process.

FIG. 4 is a diagram schematically illustrating a semiconductor processing apparatus according to example embodiments.

Referring to FIG. 4, a semiconductor processing apparatus 300 according to example embodiments may include a chamber housing 301, an optical path controller 310, a light source 320, a photodetector 330, a processor 340, and the like. In an example embodiment illustrated in FIG. 4, a cylindrical space may be present inside the chamber housing 301, and a substrate support 305 on which the wafer W may be seated may be disposed inside the chamber housing 301. The chamber housing 301 and the substrate support 305 may both be considered part of a chamber.

On the other hand, one window 307 may be provided in the chamber housing 301. The window 307 may be formed of a material such as quartz or the like so that the internal space of the chamber housing 301 may be checked. An optical path controller 310 may be attached to the window 307.

The optical path controller 310 is connected to the light source 320 and the photodetector 330 and may include a plurality of mirrors. At least one of the plurality of mirrors included in the optical path controller 310 may reflect the light output from the light source 320 and advance the optical signal into the internal space of the chamber housing 301 through the window 307. In addition, at least another mirror among the plurality of mirrors included in the optical path controller 310 changes the path of the optical signal that has passed through the window 307 after being reflected at least once in the internal space of the chamber housing 301, and may allow (e.g., provide/direct) light to be incident on the photodetector 330.

The light source 320 may emit light within a predetermined wavelength band. The operation of the light source 320 is controlled by the processor 340, and as described above, the light emitted from the light source 320 may be reflected from (e.g., by) at least one of the mirrors included in the optical path controller 310 and may be incident on the internal space of the chamber housing 301 as an optical signal. In example embodiments, the light source 320 includes a laser, a xenon lamp, or the like, and may emit light in a near-infrared (NIR) wavelength band. The light emitted from the light source 320 is transmitted to the optical path controller 310 through an optical fiber or the like. Depending on example embodiments, the optical path controller 310 may include a collimator disposed in the path of light output from the light source 320. By using a collimator, the straightness of light may be increased.

The optical signal that enters the internal space of the chamber housing 301 by the optical path controller 310 may be reflected one or more times from the inner wall of the chamber housing 301 and then return to the optical path controller 310 through the window 307. The optical path controller 310 may advance the optical signal having returned after being reflected from (e.g., by) the inner wall of the chamber housing 301, to the photodetector 330. For example, the optical signal may be reflected one or more times from at least one of the plurality of mirrors included in the optical path controller 310, pass through the collimator, and be incident on the photodetector 330 with improved straightness.

The photodetector 330 detects the intensity of the optical signal, and, for example, may detect the intensity with wavelength band of the optical signal. For example, the window 307 is installed at a height not far from the upper surface of the substrate support 305, and the optical signal incident through the window 307 travels in a direction substantially parallel to the upper surface of the substrate support 305 and may be reflected from (e.g., by) the inner wall of the chamber housing 301. While traveling through the internal space of the chamber housing 301, part of the optical signal may be absorbed by radicals present on the substrate support 305, and therefore, the intensity of the optical signal coming through the window 307 and the intensity of the optical signal going out through the window 307 may be different.

The processor 340 compares the intensity of each wavelength band of the light output from the light source 320 with the intensity of each wavelength band of the optical signal detected by the photodetector 330, and may determine the radical density and/or distribution inside the chamber housing 301. The processor 340 may determine the density and/or distribution of radicals present in the area containing the path along which the optical signal traveled inside the chamber housing 301.

Accordingly, by changing the path along which the optical signal travels inside the chamber housing 301, the density and/or distribution of radicals present in different areas inside the chamber housing 301 may be determined. In example embodiments, the processor 340 changes the path along which the optical signal travels in the internal space of the chamber housing 301 by moving a plurality of mirrors included in the optical path controller 310, and the density and/or distribution of radicals may be determined in each of the different regions defined inside the chamber housing 301.

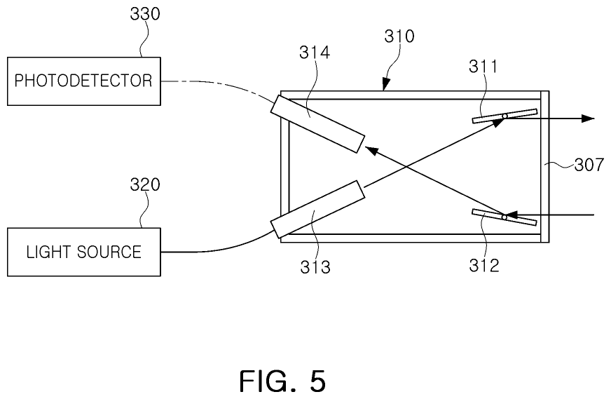

FIG. 5 is a diagram schematically illustrating an optical path controller included in a semiconductor processing apparatus according to example embodiments.

Referring to FIG. 5, the optical path controller 310 according to example embodiments may include a first mirror 311, a second mirror 312, a first collimator 313, a second collimator 314, and the like. The first mirror 311, the second mirror 312, the first collimator 313, and the second collimator 314 are disposed in a case (e.g., a housing) that blocks external light and provides a dark space, and one side of the case may be attached to the window 307 provided in the chamber housing.

The light emitted from the light source 320 is incident on the first collimator 313 through a light guide such as an optical fiber, and straightness of the light may be enhanced. Light passing through the first collimator 313 is reflected from (e.g., by) the first mirror 311 and may be incident as an optical signal into the internal space of the chamber housing through the window 307. Since the light reflected by the first mirror 311 is incident as an optical signal into the internal space of the chamber housing through the window 307, the path along which the optical signal travels in the internal space of the chamber housing may vary depending on the attitude (e.g., position/angle) of the first mirror 311, or the like.

On the other hand, the optical signal that passes through the window 307 and enters the chamber housing is reflected one or more times from the inner wall of the chamber housing while traveling in the internal space of the chamber housing, and may return to the optical path controller 310 through the window 307. The returned optical signal may be reflected from (e.g., by) the second mirror 312 (after the returned optical signal exits the internal space of the chamber housing through the window 307) and then transmitted to the photodetector 330 through the second collimator 314. The photodetector 330 and the second collimator 314 may be connected through a light guide such as an optical fiber.

A portion of the optical signal that is reflected from (e.g., by) the first mirror 311 and then passes through the window 307 may be absorbed by radicals present in the internal space of the chamber housing. Therefore, the intensity of the optical signal passing through the window 307, being reflected from (e.g., by) the second mirror 312, and then incident on the photodetector 330, may be weaker in at least some wavelength bands, than the intensity of the optical signal that passes through the window 307 and enters the internal space of the chamber housing. In example embodiments, the density and/or distribution of radicals present in the internal space of the chamber housing may be determined using the difference in intensity of the optical signal.

Additionally, in example embodiments, the path of the optical signal may be changed by moving the first mirror 311 and the second mirror 312. Therefore, with just one window 307 installed in the chamber housing, the distribution of radicals and density differences throughout the internal space of the chamber housing may be determined, and since semiconductor processing apparatuses may be continuously disposed, the degree freedom of the semiconductor processing line may be improved.

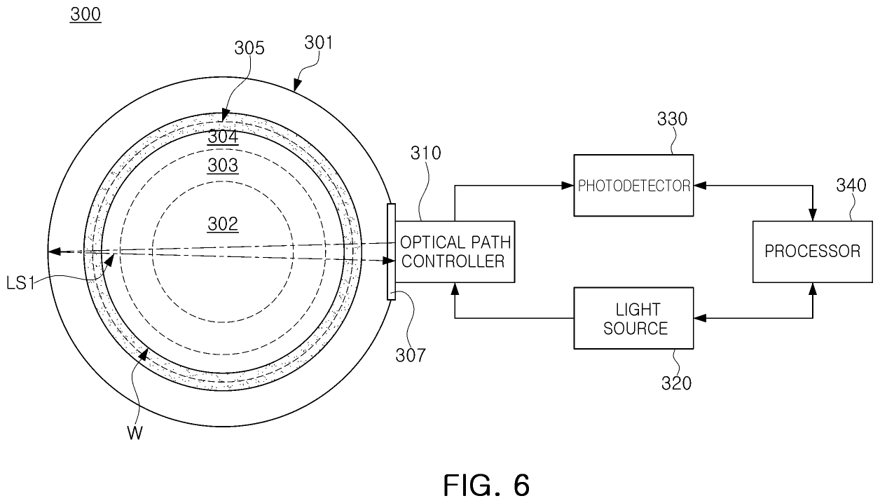

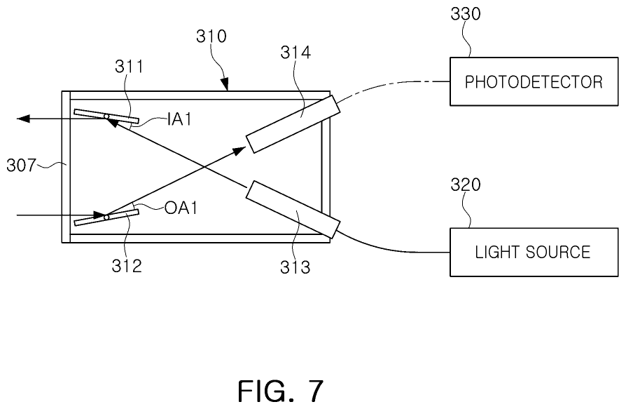

FIGS. 6 and 7 are drawings illustrating the operation of a semiconductor processing apparatus according to example embodiments.

First, referring to FIG. 6, a semiconductor processing apparatus 300 according to example embodiments may include a chamber housing 301, an optical path controller 310, a light source 320, a photodetector 330, a processor 340, and the like. The internal space of the chamber housing 301 may be cylindrical, and a substrate support 305 on which the wafer W may be placed may be disposed inside the chamber housing 301 (e.g., in the internal space). To perform a semiconductor process on the wafer W, plasma is formed inside the chamber housing 301, and radicals may be distributed into the space above the substrate support 305.

In example embodiments, while a semiconductor process is in progress, the distribution and/or density of radicals present on the substrate support 305 may be monitored. As described above, in example embodiments, radicals may be monitored based on optical signals. Light emitted from the light source 320 may enter the internal space of the chamber housing 301 as a first optical signal LS1 through the optical path controller 310. A first optical signal LS1 may be reflected one or more times in the internal space of the chamber housing 301 and then be incident again on the optical path controller 310 through the window 307.

The photodetector 330 may detect the intensity of the first optical signal LS1 incident on the optical path controller 310 for each wavelength band. While the first optical signal LS1 travels in the internal space of the chamber housing 301, the signal intensity may be weakened by being absorbed by radicals. The processor 340 compares the intensity of the first optical signal LS1 detected by the photodetector 330 with the intensity of the first optical signal LS1 emitted by the light source 320 and incident on the window 307, thereby determining the distribution and/or density of radicals present in the internal space of the chamber housing 301. In detail, the processor 340 may detect the difference in intensity of the first optical signal LS1 before and after being incident on the window 307, and use the detected difference to determine the distribution and/or density of radicals. For example, the processor 340 may compare the intensity for respective wavelength bands.

In an example embodiment illustrated in FIG. 6, the first optical signal LS1 travels along a first path to be reflected once from (e.g., by) the inner wall of the chamber housing 301, and may return to the optical path controller 310 through the window 307. To generate the first optical signal LS1 moving along the path illustrated in FIG. 6, the attitudes (e.g., positions/angles) of the first mirror 311 and the second mirror 312 included in the optical path controller 310 may be adjusted (e.g., by the processor 340).

Referring to FIG. 7 together with FIG. 6, the light emitted from the light source 320 may enter the first mirror 311 at a first angle of incidence IA1 and may then be reflected to pass through the window 307 as the first optical signal LS1. In addition, the first optical signal LS1 reflected once from (e.g., by) the inner wall of the chamber housing 301 may pass through the window 307 and then be reflected from (e.g., by) the second mirror 312 at a first emission angle OA1 and then be incident on the photodetector 330.

As illustrated in FIG. 6, first to third internal regions 302 to 304 may be defined in the internal space of the chamber housing 301. The first to third internal regions 302 to 304 may be arranged in a direction parallel to the upper surface of the substrate support 305 and away from the center of the substrate support 305. Accordingly, the internal regions 302 to 304 may be at different positions in the direction. For example, in one direction (e.g., in the direction), a second internal region 303 may be defined between the first internal region 302 and the third internal region 304.

The first optical signal LS1 traveling along the first path may pass through the first internal region 302, longer than passing through the second internal region 303 and the third internal region 304. Accordingly, the first optical signal LS1 may be most affected by the radicals present in the first internal region 302, and the processor 340 may determine the density and the like of radicals present in the first internal region 302 by using the difference between the intensity of the first optical signal LS1 output from the optical path controller 310 and the intensity of the first optical signal LS1 having returned to the optical path controller 310.

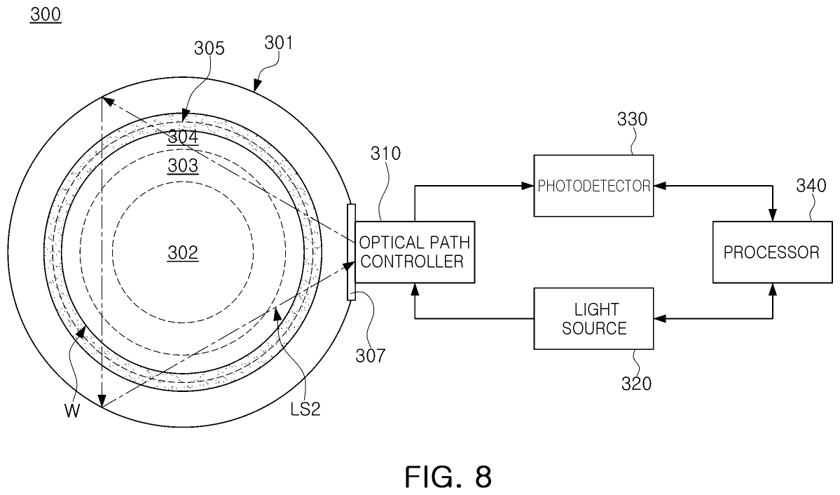

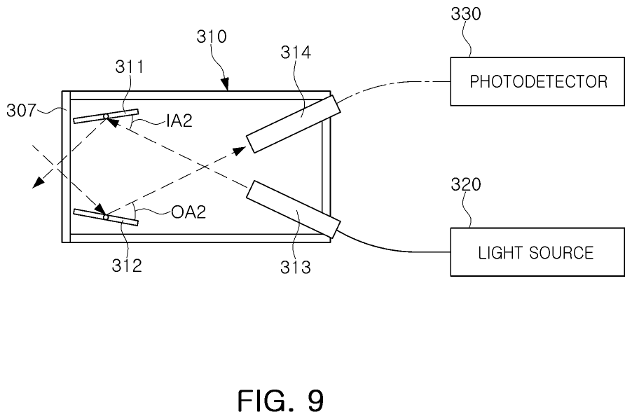

FIGS. 8 and 9 are drawings illustrating the operation of a semiconductor processing apparatus according to example embodiments.

Referring to FIG. 8, a semiconductor processing apparatus 300 according to example embodiments may include a chamber housing 301, an optical path controller 310, a light source 320, a photodetector 330, a processor 340, and the like. The internal space of the chamber housing 301 may be cylindrical, and a substrate support 305 on which the wafer W may be placed may be disposed inside the chamber housing 301. To perform a semiconductor process on the wafer W, plasma is formed inside the chamber housing 301, and radicals may be distributed into the space above the substrate support 305.

In the example embodiment illustrated in FIG. 8, the second optical signal LS2 may travel along a second path different from the first path along which the first optical signal LS1 travels. To generate the second optical signal LS2, the attitudes (e.g., positions/angles) of the first mirror 311 and the second mirror 312 may be adjusted as illustrated in FIG. 9.

Referring to FIG. 9, the light emitted from the light source 320 and passing through the first collimator 313 is incident on the first mirror 311 at a second angle of incidence IA2 and may then pass through the window 307 as the second optical signal LS2. The second angle of incidence IA2 may be greater than the first angle of incidence IA1. In addition, the second optical signal LS2, which has passed through the window 307 after being reflected in the internal space of the chamber housing 301, may be reflected from (e.g., by) the second mirror 312 and may then be incident on the second collimator 314 at the second emission angle OA2. The second emission angle OA2 may be greater than the first emission angle OA1.

Referring again to FIG. 8, the second optical signal LS2 having left the optical path controller 310 may be reflected twice on the inner wall of the chamber housing 301 and then returns to the optical path controller 310 through the window 307. Therefore, as illustrated in FIG. 8, the second optical signal LS2 overlaps the second internal region 303 the most, compared to the first internal region 302 and the third internal region 304, and may be most affected by radicals present in the second internal region 303. Therefore, the processor 340 may determine the density and the like of radicals present in the second internal region 303, using the difference between the intensity of the second optical signal LS2 leaving the optical path controller 310 and the intensity of the second optical signal LS2 returning to the optical path controller 310.

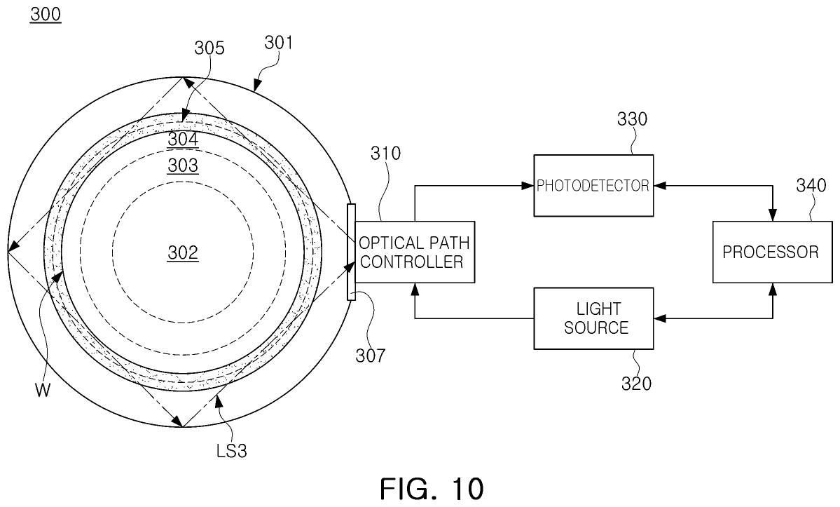

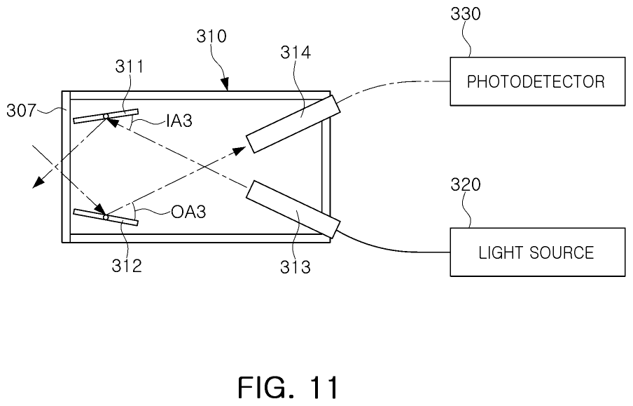

FIGS. 10 and 11 are drawings illustrating the operation of a semiconductor processing apparatus according to example embodiments.

Referring to FIG. 10, a semiconductor processing apparatus 300 according to example embodiments may include a chamber housing 301, an optical path controller 310, a light source 320, a photodetector 330, a processor 340, and the like. The internal space of the chamber housing 301 may be cylindrical, and a substrate support 305 on which the wafer W may be placed may be disposed inside the chamber housing 301. To perform a semiconductor process on the wafer W, plasma is formed inside the chamber housing 301, and radicals may be distributed into the space above the substrate support 305.

In an example embodiment illustrated in FIG. 10, a third optical signal LS3 may proceed along a third path that is different from the first path that is the travel path of the first optical signal LS1 and the second path that is the travel path of the second optical signal LS2. To generate the third optical signal LS3, the attitudes (e.g., positions/angles) of the first mirror 311 and the second mirror 312 may be adjusted as illustrated in FIG. 11.

Referring to FIG. 11, the light emitted from the light source 320 and passing through the first collimator 313 may be incident on the first mirror 311 at a third angle of incidence IA3 and then pass through the window 307 as the third optical signal LS3. The third angle of incidence IA3 may be greater than the second angle of incidence IA2. In addition, the third optical signal LS3, which has passed through the window 307 after being reflected in the internal space of the chamber housing 301, may be reflected from (e.g., by) the second mirror 312, and may be incident on the second collimator 314 at the third emission angle OA3. The third emission angle OA3 may be greater than the second emission angle OA2.

Referring again to FIG. 10, the third optical signal LS3 leaving the optical path controller 310 may be reflected three times on the inner wall of the chamber housing 301 and then return to the optical path controller 310 through the window 307. Therefore, as illustrated in FIG. 10, compared to the first internal region 302 and the second internal region 303, the third optical signal LS3 overlaps most with the third internal region 304 closest to the edge of the wafer W and the substrate support 305, and may be most affected by radicals present in the third internal region 304. Therefore, the processor 340 may determine the density of radicals present in the third internal region 304, using the difference between the intensity of the third optical signal LS3 leaving the optical path controller 310 and the intensity of the third optical signal LS3 returning to the optical path controller 310.

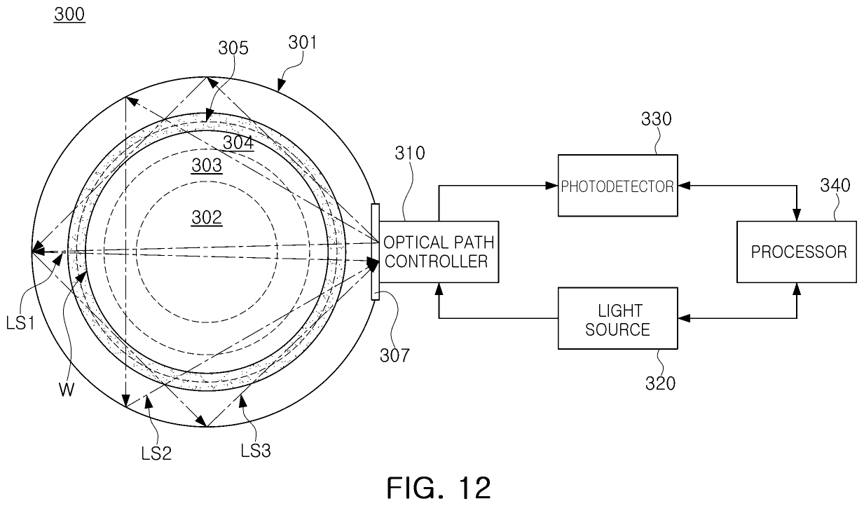

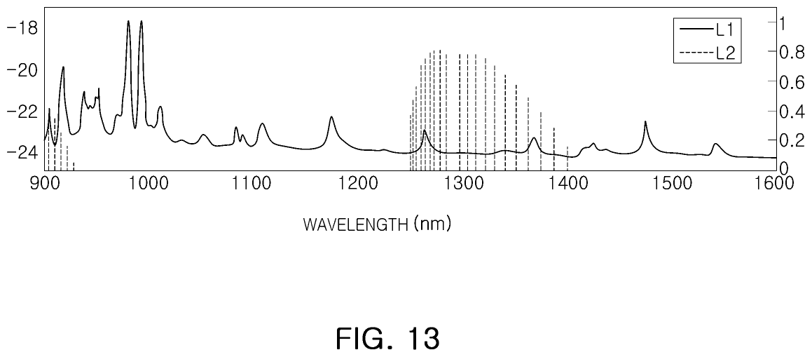

FIGS. 12 and 13 are drawings illustrating the operation of a semiconductor processing apparatus according to example embodiments.

As previously described with reference to FIGS. 6 to 11, in example embodiments, optical signals LS1, LS2, and LS3 traveling through different paths are irradiated into the internal space of the chamber housing 301, and therefore, the distribution and/or density of radicals present in each of the first to third internal regions 302 to 304 may be determined. Since the distribution and/or density of radicals required for real-time control of the semiconductor processing apparatus 300 may be measured using only one window 307 (i.e., a single window), the degree of freedom in disposing the semiconductor processing apparatus 300 may be increased.

Referring to FIG. 12, in each of the optical signals LS1, LS2, and LS3, the number of times they are reflected from (e.g., by) the inner wall of the chamber housing 301 and the lengths of the paths on/through which they move inside the chamber housing 301 may be different. For example, the first optical signal LS1 may be reflected once, the second optical signal LS2 may be reflected twice, and the third optical signal LS3 may be reflected three times.

Additionally, due to path differences, a shortest distance from the center of the substrate support 305 may also appear differently in the optical signals LS1, LS2, and LS3. For example, in a direction parallel to the upper surface of the substrate support 305 and away from the center of the substrate support 305, a shortest distance from the center of the substrate support 305 may be the shortest for the first optical signal LS1 and the longest for the third optical signal LS3.

The processor 340 may compare the intensity of the incident light leaving the optical path controller 310 and proceeding to the internal space of the chamber housing 301, with the intensity of the emitted light that is reflected one or more times in the internal space of the chamber housing 301 and then returned to the optical path controller 310, for the respective optical signals LS1, LS2, and LS3, and may determine the distribution and/or density of radicals present in each of the first to third internal regions 302 to 304. For convenience of measurement, the processor 340 may use the intensity of light emitted by the light source 320 as the intensity of incident light for each of the optical signals LS1, LS2, and LS3 incident on the internal space of the chamber housing 301. Additionally, the processor 340 may use the intensity detected by the photodetector 330 as the intensity of emitted light for each of the optical signals LS1, LS2, and LS3 returned to the optical path controller 310.

The light source 320 is a source that emits light and includes a laser, a xenon lamp, or the like, and for example, the light source 320 may emit light in a near-infrared wavelength band. The intensity of light emitted by the light source 320 may vary depending on a wavelength band. Accordingly, the photodetector 330 may be configured to detect the intensity of emitted light for each of the optical signals LS1, LS2, and LS3 in the wavelength band in which the light emitted by the light source 320 is distributed. The processor 340 may calculate the intensity difference between incident light and emitted light for each of the optical signals LS1, LS2, and LS3 in at least some of the wavelength bands, and based thereon, may determine the distribution and/or density of radicals present in each of the first to third internal regions 302 to 304.

Referring to FIG. 13, a first spectrum L1 provided by measuring the intensity of incident light of one of the optical signals LS1, LS2, and LS3, and a second spectrum L2 representing the intensity of incident light absorbed by radicals while traveling through the internal space of the chamber housing 301, are illustrated. As illustrated in FIG. 13, radicals may absorb light in a specific wavelength band. Accordingly, the processor 340 may calculate the difference in intensity between the optical signals LS1, LS2, and LS3 in a wavelength band in which radicals are known to absorb light, and based thereon, may determine the distribution and/or density of the radicals.

For example, when the density and/or amount of radicals present in the third internal region 304 through which the third optical signal LS3 passes is more than the density and/or amount of radicals present in the second internal region 303 through which the second optical signal LS2 passes, the intensity difference between the incident light and the emitted light calculated from the second optical signal LS2 may be smaller than the intensity difference between the incident light and the emitted light calculated from the third optical signal LS3. The processor 340 may calculate measurement results from the intensity distribution of the optical signals LS1, LS2, and LS3 for respective wavelength bands, and control the semiconductor processing apparatus 300 in real time using the measurement results. Therefore, the yield of the semiconductor process may be improved by reducing the difference in distribution of radicals in the space above the substrate support 305 and the wafer W.

However, as illustrated in FIG. 12, the paths along which the respective optical signals LS1, LS2, and LS3 travel through the internal space of the chamber housing 301 may have length differences. For example, the first path, which is the travel path of the first optical signal LS1, may be shorter than the second path of the second optical signal LS2 and the third path of the third optical signal LS3.

Therefore, even when radicals are uniformly present in the respective first to third internal regions 302 to 304, the intensity difference between the incident light and the emitted light calculated for each of the optical signals LS1, LS2, and LS3 may appear different. For example, when radicals are uniformly distributed in the internal space of the chamber housing 301, the difference in intensity between the incident light and the emitted light is calculated as the smallest for the first optical signal LS1 with the shortest travel path, and for the third optical signal LS3, which has the longest travel path, the difference in intensity between the incident light and the emitted light may be calculated to be the largest.

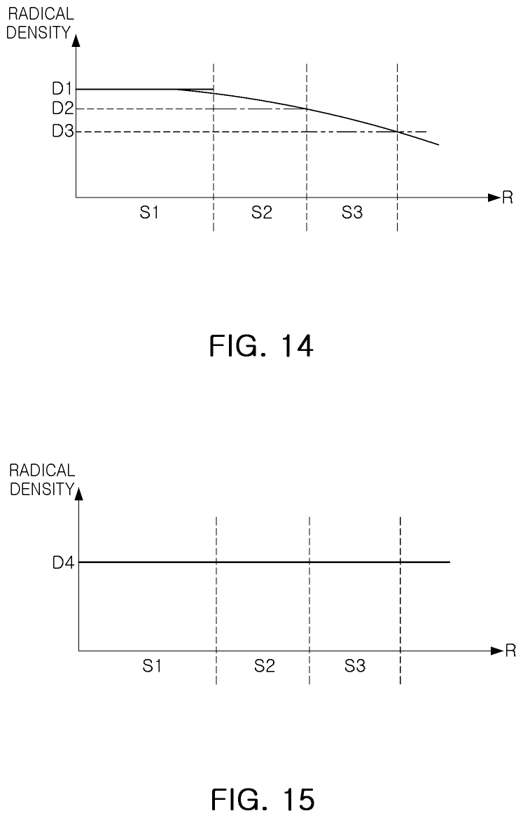

In example embodiments of the present inventive concept, the density and/or distribution of radicals may be determined by compensating for differences in the paths of each of the optical signals LS1, LS2, and LS3. Therefore, the accuracy of measuring radicals may be improved, which will be described in more detail with reference to FIGS. 14 and 15.

FIGS. 14 and 15 are diagrams illustrating a method of measuring radical distribution in a semiconductor processing apparatus according to example embodiments. The radical distribution may be measured by a processor (e.g., the processor 340 or a processor 440 (FIG. 17)).

In each of example embodiments described with reference to FIGS. 14 and 15, the density of radicals present in the internal space of the chamber housing may be uniform. Therefore, assuming that the instrumentation has been run ideally, the radical density for each of the internal regions S1-S3 defined in the internal space of the chamber housing may be calculated to be the same value. The internal regions S1-S3 may be defined in the form of concentric circles along the radial direction (R) parallel to the upper surface of the substrate support and away from the center of the substrate support in the internal space of the chamber housing.

However, the path of the first optical signal irradiated into the internal space of the chamber housing to measure the radical density of the first internal region S1 may be shorter than the path of the second optical signal irradiated into the internal space of the chamber housing to measure the radical density of the second internal region S2. In addition, the path of the second optical signal irradiated into the internal space of the chamber housing to measure the radical density of the second internal region S2 may be shorter than the path of the third optical signal irradiated into the internal space of the chamber housing to measure the radical density of the third internal region S3. Therefore, in the third optical signal, which should pass through more radicals due to the difference in the progress/travel path, the difference in intensity between the incident light and the emitted light appears the largest, and it may be incorrectly measured that the density of radicals has the lowest intensity D3 in the third internal region S3, has the highest intensity D1 in the first internal region S1, and has an intermediate intensity D2 in the second internal region S2, as illustrated in FIG. 14.

In example embodiments of the present inventive concept, the intensity difference between incident light and exit light is calculated for each of the first to third optical signals, and in this case, a task of compensating for differences in the travel paths of the respective first to third optical signals may be additionally performed. As an example, the difference in intensity between the incident light and the emitted light measured for the first optical signal may be divided by the length of the path of the first optical signal, the difference in intensity between the incident light and the emitted light measured for the second optical signal may be divided by the length of the path of the second optical signal, and the difference in intensity between the incident light and the emitted light measured for the third optical signal may be divided by the length of the travel path of the third optical signal.

Using the above method, the difference in intensity between incident and emitted light due to light absorption of radicals in each of the first to third optical signals may be accurately measured regardless of the difference in travel path length. By compensating for the difference in the travel paths of each of the first to third optical signals, as illustrated in FIG. 15, the radical densities in the respective first to third internal regions S1-S3 may be calculated with the same intensity D4.

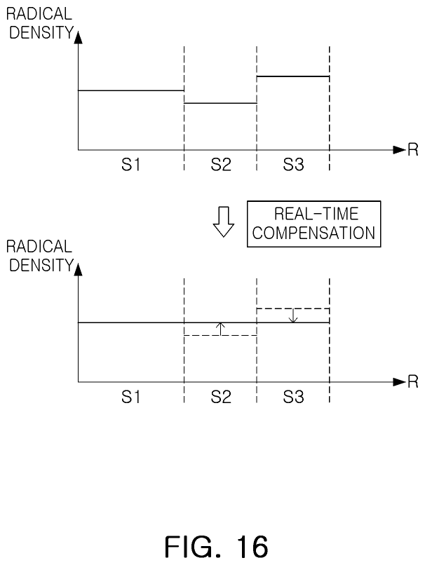

FIG. 16 is a diagram illustrating the operation of a semiconductor processing apparatus according to example embodiments.

As described above, the semiconductor processing apparatus according to example embodiments may measure the radical density and the like of each of the plurality of internal regions S1-S3, using the difference in intensity between the incident light and the exit light of the optical signal reflected once or more in the internal space of the chamber housing. In addition, the yield of the semiconductor process may be improved by controlling the semiconductor processing apparatus in real time based on the radical density measured in this manner.

The first (top) drawing of FIG. 16 may be a graph illustrating the results of measuring the radical density of each of the plurality of internal regions S1-S3 for real-time control of a semiconductor processing apparatus. Referring to FIG. 16, compared to the radical density in the first internal region S1, the radical density of the second internal region S2 may be relatively low, and the radical density of the third internal region S3 may be relatively high.

The processor that controls the semiconductor processing apparatus in real time refers to these measurement results, and as illustrated in the second drawing of FIG. 16, may control a semiconductor processing apparatus such that the radical density of the second internal region S2 increases and the radical density of the third internal region S3 is reduced. For example, a semiconductor processing apparatus includes an ion blocker having through-holes that allow radicals to pass, and the ion blocker may include a plurality of regions whose temperature may be individually controlled. The processor may adjust the recombination coefficient of radicals in the through-holes by increasing or decreasing the temperature of each of the plurality of regions. Accordingly, the processor may adjust the temperature of respective regions included in the ion blocker so that respective temperatures of the second internal region S2 and the third internal region S3 change differently from each other, and may uniformly maintain the radical density of each of the internal regions S1-S3.

Areas included in the ion blocker and internal regions S1-S3 defined in the internal space of the chamber housing may correspond to each other. In example embodiments, the regions included in the ion blocker may be arranged in a concentric circle shape in a direction away from the center of the ion blocker, and this structure may be understood by referring to the example embodiment previously illustrated in FIG. 3.

The processor may define internal regions S1-S3 that divide the internal space of the chamber housing to correspond to a plurality of regions included in the ion blocker. By matching the areas included in the ion blocker with the internal regions S1-S3 defined in the internal space of the chamber housing, the temperature of each area included in the ion blocker may be controlled, thereby effectively adjusting the radical density of each of the internal regions S1-S3 and uniformly maintaining the radical distribution in the internal space of the chamber housing.

FIG. 17 is a diagram illustrating the operation of a semiconductor processing apparatus according to example embodiments.

Referring to FIG. 17, a semiconductor processing apparatus 400 according to example embodiments may include a chamber housing 401, an optical path controller 410, a light source 420, a photodetector 430, a processor 440, and the like. The internal space of the chamber housing 401 may be cylindrical, and a substrate support 405 on which the wafer W may be seated may be disposed inside the chamber housing 401. To perform a semiconductor process on the wafer W, plasma is formed inside the chamber housing 401, and radicals may be distributed into the space above the substrate support 405.

In an example embodiment illustrated in FIG. 17, the internal space of the chamber housing 401 may be divided into two, a first internal region 402 and a second internal region 403. The first internal region 402 and the second internal region 403 may be arranged along a direction parallel to the upper surface of the substrate support 405 and away from the center of the substrate support 405.

To monitor the distribution of radicals, light emitted from the light source 420 may be incident on the internal space of the chamber housing 401 as a first optical signal LS1 through the optical path controller 410. The first optical signal LS1 may be reflected once in the internal space of the chamber housing 401 and then be incident again to the optical path controller 410 through the window 407. The photodetector 430 may detect the intensity of the first optical signal LS1 incident on the optical path controller 410 for each wavelength band. The processor 440 may calculate the intensity difference between the incident light and the emitted light for the first optical signal LS1 and determine the density of radicals, based thereon.

Similarly, light emitted from the light source 420 may enter the internal space of the chamber housing 401 as the second optical signal LS2 through the optical path controller 410. The second optical signal LS2 may be reflected three times in the internal space of the chamber housing 401 and then be incident again on the optical path controller 410 through the window 407. The photodetector 430 may detect the intensity of the second optical signal LS2 incident on the optical path controller 410 for each wavelength band. The processor 440 may calculate the intensity difference between the incident light and the emitted light for the second optical signal LS2 and determine the density of radicals based thereon.

However, even in the example embodiment illustrated in FIG. 17, to reduce/prevent measurement errors due to differences in the travel paths of the first optical signal LS1 and the second optical signal LS2, the processor 440 may divide the intensity difference between the incident light and the emitted light calculated for each of the first optical signal LS1 and the second optical signal LS2, by each travel path. By performing this operation, the difference in intensity between the incident light and the emitted light, occurring per unit length of the traveling path, may be calculated, and the radical density of each of the first internal region 402 and the second internal region 403 may be measured more accurately.

As set forth above, according to example embodiments, an optical path controller is disposed on a window of a chamber housing, and the optical path controller may input an optical signal into the internal space of the chamber housing through the window. The incident optical signal is reflected at least once in the internal space and then transmitted to a photodetector through the window and the optical path controller. The photodetector may detect the intensity of the optical signal in each wavelength band. By using the optical signal reflected in the internal space, the distribution of radicals present in the internal space of the chamber housing may be accurately determined through the window provided in the chamber housing, and the yield of the semiconductor process may be improved by controlling the semiconductor processing apparatus in real time based on radical distribution.

While example embodiments have been illustrated and described above, it will be apparent to those skilled in the art that modifications and variations could be made without departing from the scope of the present inventive concept as defined by the appended claims.

What is claimed is:

1. A semiconductor processing apparatus comprising:
a chamber housing having only one window;
a substrate support in an internal space of the chamber housing;
a light source configured to emit light within a predetermined wavelength band;
an optical path controller including a first mirror configured to reflect the light as a first optical signal that enters the internal space of the chamber housing through the window, and a second mirror configured to reflect the first optical signal after it exits the internal space through the window;
a photodetector configured to detect a first intensity of the first optical signal; and
a processor configured to adjust the first mirror and the second mirror to obtain a second intensity of a second optical signal, traveling along a second path different from a first path of the first optical signal, in the internal space, from the photodetector, and determine a radical distribution in the internal space based on the first intensity and the second intensity.

2. The semiconductor processing apparatus of claim 1,
wherein an inner wall of the chamber housing is configured to reflect the first optical signal N times in the internal space as the first optical signal travels along the first path, and to reflect the second optical signal M times in the internal space as the second optical signal travels along the second path,
wherein each of N and M is a natural number, and
wherein N is different from M.

3. The semiconductor processing apparatus of claim 1, wherein a length of the first path is different from a length of the second path.

4. The semiconductor processing apparatus of claim 3, wherein, in a direction parallel to an upper surface of the substrate support and away from a center of the substrate support, a shortest distance between the center of the substrate support and the first path is shorter than a shortest distance between the center of the substrate support and the second path.

5. The semiconductor processing apparatus of claim 4,
wherein the processor is configured to determine the radical distribution in a first internal region of the internal space based on the first intensity, and determine the radical distribution in a second internal region of the internal space based on the second intensity, and
wherein the second internal region is at a different position from the first internal region in the direction.

6. The semiconductor processing apparatus of claim 1, wherein the processor is further configured to adjust the first mirror and the second mirror to obtain a third intensity of a third optical signal, traveling along a third path different from the first path and the second path in the internal space, from the photodetector.

7. The semiconductor processing apparatus of claim 6, wherein an inner wall of the chamber housing is configured to reflect the second optical signal in the internal space a number of times that is greater than a number of times the inner wall of the chamber housing is configured to reflect the first optical signal in the internal space, and is less than a number of times the inner wall of the chamber housing is configured to reflect the third optical signal in the internal space.

8. The semiconductor processing apparatus of claim 6, wherein the processor is configured to determine the radical distribution in a first internal region of the internal space based on the first intensity, determine the radical distribution in a second internal region of the internal space based on the second intensity, and determine the radical distribution in a third internal region of the internal space based on the third intensity, and
wherein the first internal region, the second internal region, and the third internal region are sequentially defined in a direction parallel to an upper surface of the substrate support and away from a center of the substrate support.

9. The semiconductor processing apparatus of claim 1, wherein the optical path controller further includes a first collimator between the light source and the first mirror, and a second collimator between the second mirror and the photodetector.

10. The semiconductor processing apparatus of claim 9, wherein the first mirror, the second mirror, the first collimator, and the second collimator are in a housing that is configured to block external light.

11. The semiconductor processing apparatus of claim 1, further comprising:
a first light guide connected between the light source and the optical path controller; and
a second light guide connected between the optical path controller and the photodetector.

12. A semiconductor processing apparatus comprising;
a chamber housing having a single window;
a substrate support in an internal space of the chamber housing;
a plasma source in the internal space of the chamber housing;
an ion blocker dividing the internal space of the chamber housing into a first space in which the plasma source is configured to generate plasma, and a second space in which the substrate support is located, and including a plurality of regions each having a plurality of through-holes;
a temperature control unit configured to individually control temperature of each of the plurality of regions;
an optical path controller attached to the window, and configured to generate an optical signal that enters the second space through the window, reflects in the internal space, and then returns to the window; and
a processor,
wherein the processor is configured to determine a radical distribution of the second space by detecting an intensity of the optical signal when radicals of the plasma move into the second space through the plurality of through-holes.

13. The semiconductor processing apparatus of claim 12, wherein the processor is further configured to determine a radical density of each of a plurality of internal regions defined in the second space by changing a path of the optical signal.

14. The semiconductor processing apparatus of claim 13,
wherein the plurality of regions are in a concentric circle shape in a direction away from a center of the ion blocker, and
wherein the processor is further configured to control the temperature control unit to change a temperature of at least one of the plurality of regions, based on the radical density of each of the plurality of internal regions.

15. The semiconductor processing apparatus of claim 14, wherein the plurality of internal regions correspond to the plurality of regions included in the ion blocker.

16. The semiconductor processing apparatus of claim 12, further comprising:
a light source and a photodetector, connected to the optical path controller by an optical fiber,
wherein the optical path controller includes a first mirror that is configured to reflect light emitted by the light source and direct the light to enter the second space through the window, and a second mirror that is configured to reflect the optical signal after it returns to the window and direct the optical signal to the photodetector.

17. The semiconductor processing apparatus of claim 16, wherein the processor is further configured to change a path of the optical signal by controlling positions of each of the first mirror and the second mirror.

18. A semiconductor processing apparatus comprising:
a chamber housing having a single window;
a plasma source in an internal space of the chamber housing;
a substrate support in the internal space of the chamber housing;
an ion blocker in the internal space of the chamber housing and including a plurality of through-holes each providing a path for movement of radicals of plasma that the plasma source is configured to generate in response to power applied to the plasma source; and
an optical path controller attached to the window,
wherein the ion blocker divides the internal space of the chamber housing into a first space with the plasma source therein and with the plasma generated therein, and a second space with the substrate support therein,
wherein the window faces the second space, and
wherein the optical path controller includes a first mirror that is configured to reflect light as an optical signal that enters the second space through the window, and a second mirror that is configured to reflect the optical signal after it is reflected in the second space and then returned through the window.

19. The semiconductor processing apparatus of claim 18, wherein the window is closer to the substrate support than to the ion blocker in a direction perpendicular to an upper surface of the substrate support.

20. The semiconductor processing apparatus of claim 18, wherein the first mirror is configured to reflect light in a near infrared (NIR) wavelength band, emitted by a predetermined light source.
